(19) United States
(12) Patent Application Publication
(10) Pub. No.: US 2023/0274996 A1
(43) Pub. Date: Aug. 31, 2023

(54) CHIP ARRANGEMENT, CHIP PACKAGE, METHOD OF FORMING A CHIP ARRANGEMENT, AND METHOD OF FORMING A CHIP PACKAGE

(71) Applicant: Infineon Technologies AG, Neubiberg (DE)

(72) Inventors: Stefan SCHWAB, Regensburg (DE); Edward FÜRGUT, Dasing (DE); Edmund RIEDL, Wald (DE); Harry SAX, Straubing (DE); Stefan KRIVEC, Arnoldstein (AT); Manfred PFAFFENLEHNER, Muenchen (DE); Carsten SCHAEFFER, Annenheim (AT)

(73) Assignee: Infineon Technologies AG, Neubiberg (DE)

(21) Appl. No.: 18/105,309

(22) Filed: Feb. 3, 2023

(30) Foreign Application Priority Data
Feb. 25, 2022 (DE) 10 2022 104 607.9

(51) Int. Cl. H01L 23/31; H01L 23/00; H01L 21/56

(52) U.S. Cl. CPC H01L 23/3192; H01L 21/56; H01L 23/3135; H01L 24/02; H01L 24/05; H01L 23/291

(57) ABSTRACT

A chip arrangement is provided. The chip arrangement may include a chip including a first main surface, wherein the first main surface includes an active area, a chip termination portion, and at least one contact pad. A first dielectric layer at least partially covers the chip termination portion and the active area, and at least partially exposes the at least one contact pad, and a second dielectric layer formed by atomic layer deposition over the first dielectric layer and over the at least one contact pad.

### CROSS-REFERENCE TO RELATED APPLICATION

This Utility Patent Application claims priority to German Patent Application No. 10 2022 104 607.9 filed Feb. 25, 2022, which is incorporated herein by reference.

### TECHNICAL FIELD

Various embodiments relate generally to a chip arrangement, chip package, method of forming a chip arrangement, and method of forming a chip package.

### BACKGROUND

Power semiconductor devices like, for example, insulated-gate bipolar transistors (IGBTs) of freewheeling diodes, may in many applications be exposed to an atmosphere with high humidity, because typical housings (e.g., in modules) may not be humidity tight, and inverters in which the devices may be used may, for cost reasons, not be mounted in a cabinet providing a controlled environment.

Exposing the power semiconductor devices to such an environment with high humidity, increased temperature, and a high applied voltage, may possibly lead to a failure of the device due to corrosion of a metallization layer (e.g. aluminum) or degradation of the passivation layer (e.g. imide), for example.

Another aspect is related to a high temperature reverse bias tests (HTRB tests), which many power semiconductor devices are required to pass, but which the devices may fail for various reasons.

### SUMMARY

A chip arrangement is provided. The chip arrangement may include a chip including a first main surface, wherein the first main surface includes an active area, a chip termination portion, and at least one contact pad, a first dielectric layer at least partially covering the chip termination portion and the active area, and at least partially exposing the at least one contact pad, and a second dielectric layer formed by atomic layer deposition over the first dielectric layer and over the at least one contact pad.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the invention. In the following description, various embodiments of the invention are described with reference to the following drawings, in which:

each of FIG. 1A and FIG. 1B shows a schematic illustration of a chip arrangement according to a prior art;

each of FIGS. 2A to 2D shows a schematic illustration of a chip arrangement in accordance with various embodiments;

FIG. 3 shows a schematic illustration of a chip system including a chip package in accordance with various embodiments; and

FIG. 4 shows a flow diagram of a method of forming a chip arrangement in accordance with various embodiments.

### DESCRIPTION

The following detailed description refers to the accompanying drawings that show, by way of illustration, specific details and embodiments in which the invention may be practiced.

The word “exemplary” is used herein to mean “serving as an example, instance, or illustration”. Any embodiment or design described herein as “exemplary” is not necessarily to be construed as preferred or advantageous over other embodiments or designs.

Various aspects of the disclosure are provided for devices, and various aspects of the disclosure are provided for methods. It will be understood that basic properties of the devices also hold for the methods and vice versa. Therefore, for sake of brevity, duplicate description of such properties may have been omitted.

Over the last years, customer demand for humidity rugged power devices has become stronger, and tests like the high voltage, high humidity, high temperature reverse bias test (HV-H3TRB) have been introduced as a standard qualification test to ensure a sufficient humidity ruggedness of the devices in the customer’s applications.

There are several approaches to improve the humidity ruggedness of power devices, but all come with disadvantages.

In one approach, a chip termination concept may be changed. By changing to a termination concept with a very low electric field (e.g., by using a voltage limiting device (VLD) concept) at metal edges of the chip and/or in a passivation layer (e.g., an imide layer), an improvement in the humidity ruggedness may be achieved.

However, such concepts may have the disadvantage that they are very “open”, which means that the termination area covered by metal is small and therefore such concepts are sensitive to charges originating in the passivation layers and housing materials and processes. HTRB (high temperature reverse bias test) stability may be difficult to achieve, and only at the price of a wide chip termination. Besides that, it was seen that a random, local high contamination may occur.

Using a different approach, a thick hard passivation may be applied (e.g., a nitride and/or an oxide) on top of a metal on the chip surface. The thick hard passivation may be able to improve the humidity ruggedness. However, it was shown that layers with a reasonable thickness (up to approximately 1 µm) show cracks and growth lines at the metal edges, degrading the humidity ruggedness. Extremely thick layer (e.g. oxides and/or nitrides) necessary to reach an improvement of the humidity ruggedness. Such a layer has the disadvantage that it is expensive, leads to an increased wafer bow that may be a blocking point for thin wafers, may lead to a blocking voltage drift in the HTRB test, and may not be suited for molded packages, since the layer may show cracks after temperature cycling.

In various embodiments, a chip passivation/protection barrier may be provided that may be able to address both problems, the humidity sensitivity and the HTRB failures, at the same time.

In various embodiments, one or more atomic layer deposition (ALD) layers may be deposited on completely assembled devices, e.g. on a chip arrangement including a chip, a chip passivation (e.g. silicon nitride and/or polyimide) and metal (e.g., a contact pad). This provides a barrier for humidity and/or mobile ions from getting into the imide and to the metal. A degradation of the imide and corrosion of the metal may be prevented, e.g. in a humid atmosphere, and also HTRB failures may be prevented. The respective layer may be deposited at a wafer level.

In various embodiments, one or more atomic layer deposition (ALD) layers may be deposited as substitute for chip passivations (chip passivations may for example be made of or include silicon nitride and/or polyimide). The ALD layer(s) may be deposited on a completely assembled device (e.g., on a chip arrangement including a chip, wires, a leadframe, a ceramic substrates, a PCB substrate, or the like). The ALD layer(s) may provide a barrier for humidity from getting into, for example, an isolation layer, e.g. an SiO₂ layer, and to the metal. A degradation of the e.g., isolation layer and corrosion of the metal may be prevented, e.g. in a humid atmosphere, and also HTRB failures may be prevented. The respective layer may be deposited at wafer level.

Besides the passivation and barrier function, the ALD layer may be configured as an adhesion promoter layer, for example for increasing an adhesion to an encapsulant, in particular a mold compound.

In various embodiments, an Al₂O₃ ALD layer may be suitable for protecting a chip termination portion, also referred to as an edge termination, of a chip arrangement, e.g., a power semiconductor, agains HTRB drifts.

The ALD deposited layer may for example be deposited on all top surfaces, on all top- and side surfaces, or on all surfaces and form a compact layer in every dimension. A chip passivation / protection barrier may thereby be formed.

The ALD deposited layer may for example include a stack (sandwich structure) of a plurality of stacked sub-layers (or, as another way to phrase it, a plurality of ALD layers may be provided one on top of the other). In various embodiments, Al₂O₃ may be used in combination with any, some, or all of, e.g., SiO₂, HfO₂ or TiO₂. This may result in a very low water vapour transmission rate. As a consequence, an ALD layer or layer stack may form a good moisture barrier and/or ion barrier to protect the chip edge.

Multiple passivation types are available as precursor for the ALD process.

Suitable ALD material to build up inert and chemically stable ion and/or humidity barriers may include the following: Al₂O₃, SiO₂, HfO₂, ZrO₂, TiO₂, Ta₂O₅, AlN, BN, TiN, TaN, Si₃N₄. Multilayer stacks of different materials may improve the barrier quality, e.g. to avoid crystallization of the material and to suppress pinhole formation.

Each of FIG. 1A and FIG. 1B shows a schematic illustration of a chip arrangement 100 according to a prior art, wherein FIG. 1A shows a cross-sectional view and FIG. 1B shows a top view.

The chip arrangement 100 may include a chip 104 with an active area 106 and an chip termination portion 132. FIG. 1A shows a chip arrangement 100 having a typical configuration of the chip termination portion 132 surrounding the ative area 106. The active area 106 may include one or more electronic elements like transistors, diodes, etc. for functional operation of the chip arrangement 100. The chip termination portion 132 may be configured to reduce a field strength, in particular in power applications, for protecting the chip 104 of the chip arrangement 100. The chip termination portion 132 may for example include metal rings 126 (for example using Al, AlCu, AlSiCu, Cu or combinations thereof), p/n junctions (in FIG. 1B, p-wells 122 are arranged in an n-doted bulk semiconductor material, e.g. Si or SiC, of the chip 104), a graded p-doted area (as for example shown in the embodiments of FIG. 2B to FIG. 2D), and/or regions (for example alternating regions) including polysilicon and/or silicon oxide. The polysilicon may for example be used instead of the metal 126 of FIG. 1B, alternating with a dielectric material 124 such as silicon oxide. FIG. 1B shows an example of how a chip termination portion may be configured. In particular in high power applications a large difference in electric potential (see, e.g., FIG. 1A) may occur between frontside of the chip 104 including the first surface 104S1 and an opposite backside of the chip arrangement 100 including a second surface 104S2, which may for example be configured as an emitter of an IGBT or as a cathode of a diode (the emitter/cathode is indicated as a layer 120 in FIG. 1B and FIGS. 2B to 2D, contacted by a backside metallization 114). For this reason, a metal portion 112, for example a circumferential ring at an edge portion close to an open side surface of the chip arrangement 200, may be provided for protection from the backside high voltage.

The chip termination portion may be covered by a first dielectric material 128.

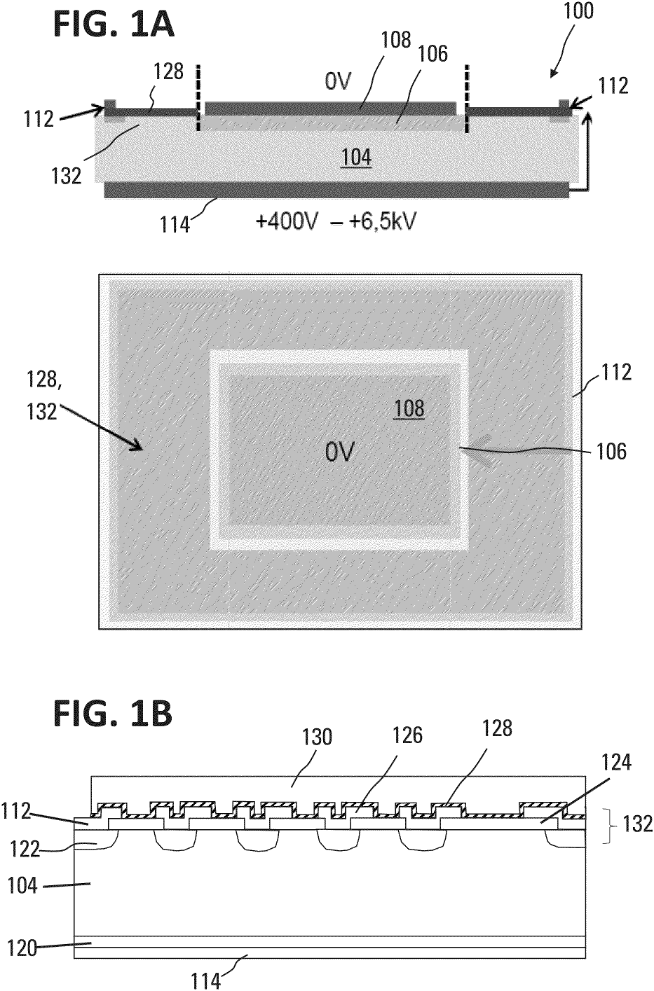

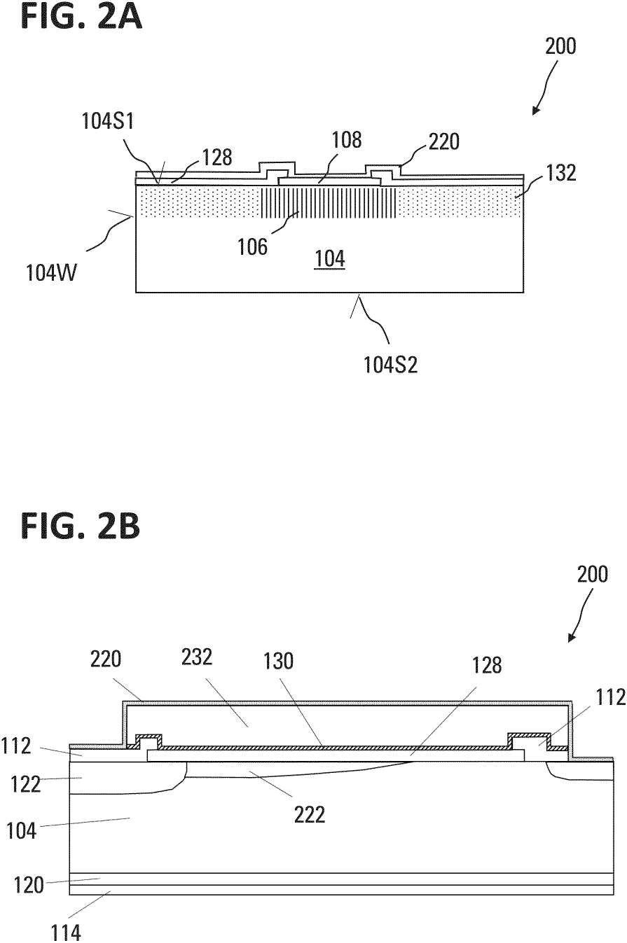

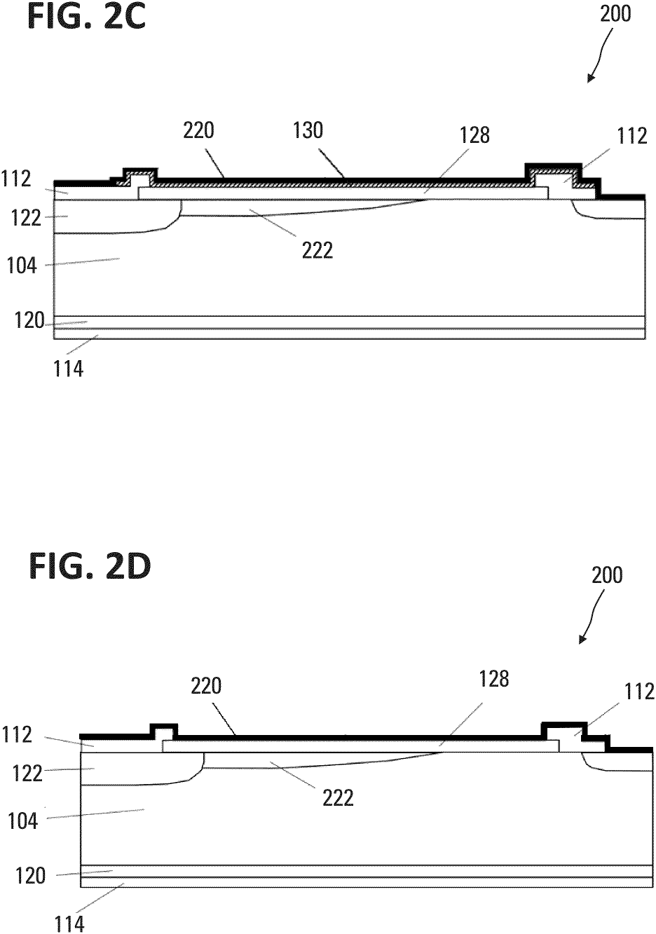

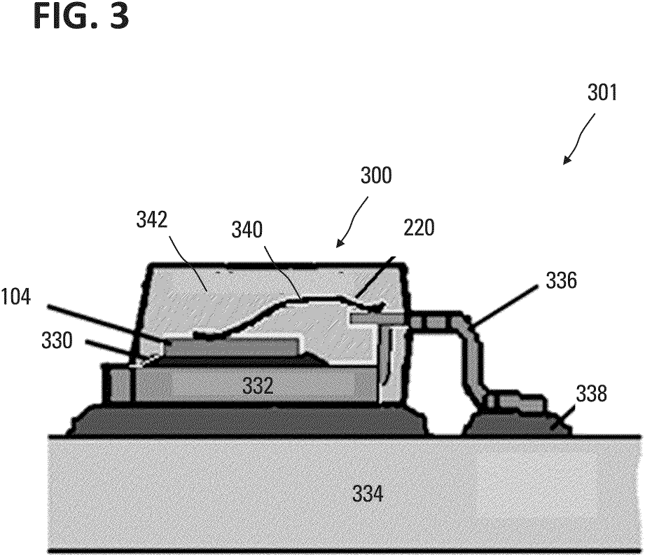

Each of FIG. 2A and FIG. 2D shows a schematic illustration of a chip arrangement 200 in accordance with various embodiments, and FIG. 3 shows a schematic illustration of a chip system 301 including a chip package 300 that includes a chip arrangement 200 in accordance with various embodiments.

The chip arrangement 200 may in various embodiments be based on a chip arrangement 100 similar or identical to a chip arrangement 100 as described in context with FIG. 1A, and may additionally include one or more ALD layers 220 as described below.

The chip arrangement 200 may include a chip 104 including a first main surface 104S1, wherein the first main surface 104S1 includes an active area 106, a chip termination portion 132, and at least one contact pad 108. The chip arrangement 200 may further include a first dielectric layer 128 at least partially covering the chip termination portion 132 and the active area 106 and at least partially exposing the at least one contact pad 106, and a second dielectric layer 220 formed by atomic layer deposition (ALD) over the first dielectric layer 128 and over the at least one contact pad 108.

The atomic layer deposition may be executed essentially as known in the art. ALD layers 220 are typically thin. The first dielectric layer 128 may be formed by processes known in the art other than ALD. Thus, the first dielectric layer(s) 128 may be thicker than the second dielectric layer 220.

The contact pad 108 may be arranged in any suitable position on the first main surface 104S1, for example in/over the active area 106, in/over the chip termination portion 132, or extending from the active area 106 to the chip termination portion 132.

Due to the ALD deposition process, the second dielectric layer 220, also referred to as ALD layer 220, may conform to the first main surface 104S1 of the chip arrangement 200. The second dielectric layer 220 may for example cover all of the first main surface 104S1, either before or after a bonding process was/is executed.

In various embodiments, the chip arrangement 200 may include a plurality of first dielectric layers 128, 130, 232 below the second dielectric layer 220 (the ALD layer). The plurality of first dielectric layers 128, 130, 232 may include a first dielectric layer 128 closest to (e.g., directly on) the bulk material of the chip 104, and optionally further first dielectric layers 130, 232 (and optionally others. The plurality of first dielectric layers 128, 130, 232 may differ regarding their material(s) and/or portions of the first surface 104S1 where they are formed. Generally, the dielectric layers arranged between the second dielectric layer 220 and the chip 104 are referred to as first dielectric layer(s) 128(, 130, 232). Unless the plurality of first dielectric layers 128, 130, 232 is referred to, only the reference number 128 may be used, but properties mentioned in the context may be understood, where appropriate, to apply to any or all of the plurality of first dielectric layers 128, 130, 232.

The first dielectric layer 128 may for example include or consist of an organic material, an oxide, and/or a nitride.

Each of the first dielectric layers 128 may for example include or consist of Al₂O₃, SiO₂, HfO₂, ZrO₂, TiO₂, Ta₂O₅, AlN, BN, TiN, TaN, Si₃N₄, and/or an organic material.

The second dielectric layer 220 may include or consist of Al₂O₃, SiO₂, HfO₂, ZrO₂, TiO₂, Ta₂O₅, AlN, BN, TiN, TaN, Si₃N₄, and/or an organic material.

A material of the second dielectric layer 220 (the top ALD layer) may differ from the material of the first dielectric layer 128 and/or from the material of the dielectric layer that forms an interface with the second dielectric layer 220.

For example, the first dielectric layer 128 may include or consist of SiO₂, and may for example form an isolation layer. The second dielectric layer 220 may for example include Al₂O₃ or any of the other materials listed above for the second dielectric layer 220. Examplary embodiments are shown in FIG. 2A and FIG. 2D.

In another example (see for example FIG. 2B and FIG. 2C), a first dielectric layer 128 may include or consist of SiO₂, and may for example form an isolation layer. Another first dielectric layer 130 may be arranged on top of the first dielectric layer 128. Yet another first dielectric layer 130 may for example include or consist of silicon nitride and/or polyimide and may form a passivation layer. The first dielectric layers 128 and 130 may in various embodiments be structured differently. For example, the metal structure 112 may be free from the first dielectric layer 128, and may be covered by the other first dielectric layer 130. The second dielectric layer 220 may for example include Al₂O₃ or any of the other materials listed above for the second dielectric layer 220. In the embodiment shown in FIG. 2B, a further first dielectric layer 232, which may for example include a polymer, e.g., an imide, may be arranged between the other first dielectric layer 130 and the ALD layer 220, for example as a passivation layer.

The first dielectric layers 128, 130, 232 and the second dielectric layer may each be formed as a layer stack including a plurality of layers, for example layers with different (e.g., alternating) materials.

The second dielectric layer 220 may for example form stacks (sandwich structures) of Al₂O₃ in combination with either SiO₂, HfO₂ or TiO₂, thereby achieving a very low water vapour transmission rate and therefore good moisture barrier properties to protect the chip edge.

For the improvement of humidity robustness, the ALD materials besides Al₂O₃ like ZrO₂, SiO₂, HfO₂, TiO₂ or Ta₂O₅ or multilayer stacks may be suitable for forming a very dense and stable ALD layer 220 that is able to survive the high voltage humidity stress conditions. Very high chemical inertness and stability was demonstrated for the ALD materials ZrO₂, SiO₂, HfO₂. It was also shown that multi layer stacks are helpful to reduce pinhole defects, which might possibly occur especially in case of a very thin ALD layer 220 (thickness < 30 nm).

In various embodiments, the deposition of the ALD layer 220 may be provided on top of an organic passivation layer (e.g., an imide) as final deposition onto the wafer (at wafer level processing), or in backend after die attach and bonding. In case of ALD depositon at wafer level, wafer testing and bonding may have to be made possible by the ALD layer 220. In other words, the ALD layer 220 needs to be thin enough to allow being pierced by probe needles for testing or for having a bond (e.g., between a bonding wire and the contact pad 108) formed through the ALD layer 220.

The ALD layer 220 may cover the first surface 104S1 of the chip 104, one or more chip sidewalls 104W, and optionally all surfaces in the chip arrangement 200 that form, in a chip package 300 that includes the chip arrangement 200, an interface to an encapsulant, in particular a mold compound, of the chip package 300. In other words, optionally, an hermetic sealing of the complete chip arrangement 200 may be provided just before molding.

In various embodiments, the ALD layer 220 may be configured as a substitute for a chip passivation.

The ALD layer 220 may cover the chip top and act as a passivation (e.g. on the metal of the chip pad 108 and on an isolation layer like the first dielectric layer 128).

The ALD layer 220 may act as a protection barrier towards multiple substances responsible for corrsosion and other degradation mechanisms, for example water, oxygen, H₂S, cations (e.g. Na⁺), anions (e.g. Cl⁻), and the like.

The ALD layer 220 covering insulating layers (the first dielectric layer(2) 128) may block an incorporation (e.g., of ions like the above mentioned cations and/or anions) in those layers 128.

In an exemplary embodiment, Al₂O₃ (deposited by ALD as the second dielectric layer 220) was arranged on SiOx (as the first dielectric layer 128) upon application of bias-temperature stress. Time-of-flight secondary ion mass spectrometry (ToF-SIMS) depth profiling shows no significant incorporation of Na⁺ ions in/underneatch the silicon oxide layer. Initially, the Na⁺ may be located in a host matrix layer, deposited on the Al₂O₃/SiOx stack.

Without the second dielectric Al₂O₃ layer 220, a significant Na⁺ peak may be detected at the SiOx/Si interface.

Other positively charged mobile alkali ions may show a similar behaviour. For example, a behaviour of Li⁺ is comparable to Na⁺. K⁺ is known to migrate even slower, whereas no indication for anionic contaminations was found (no significant movement or incorporation by bias-temperature stress for Cl⁻).

Avoiding or mitigating the ion contamination by arranging the second dielectric layer 220 helps avoid or mitigate fails induced by mobile ionsin HTRB testing.

In an experiment, an ALD layer 220 of Al₂O₃ (20 nm) was deposited around a chip arrangement 200 after die attach and wire bonding. After the second dielectric layer 220 was deposited, the chip arrangement 200 was molded with an encapsulant (e.g., a mold compound) 342 that is known to suffer from or cause severe HTRB fails. The resulting chip package 300 may have been similar or identical to the chip package 300 of FIG. 3, where the chip package 300 is mounted (e.g. soldered, using solder 338) onto a circuit board 334 to form the chip system 301. A chip package without the ALD layer 220 served as a reference.

HTRB results show that the chip package 300 with the ALD layer 220 did not show any fails in the HTRB study, while the reference group showed no fails.

The as deposited ALD Al₂O₃ layer consisted of bare Al₂O₃. This layer acts as diffusion barrier against small fast diffusion ions, as e.g. alkali ions. Failure mechanisms due to the presence of such ions in active device regions may be counteracted by the use of Al₂O₃.

While the current experiment shows an improvement in HTRB, there is also a possibility that a behaviour of chip arrangements 200 in H3TRB or HV H3TRB tests may be improved.

As seen in the results, the ALD layer 220 used could completely avoid HTRB fails while the reference group showed severe fails. While this effect was determined to occur using a thickness of 20 nm (Al₂O₃) for the second dielectric layer 220, it is expected that a thinner layer may show a similar effect.

In the current experiment, the ALD layer 220 was deposited after die attach and wire bonding (prior to molding), which may result in a configuration similar or identical to the embodiment shown in FIG. 3, with the second dielectric layer 220 covering not only the first chip surface 104S1, but also a carrier 232 (e.g., a heat sink and/or a leadframe) to which the chip 104 is attached by a die attach material 330, a bond wire 340, and mold-internal surfaces of a chip package terminal 336.

In various other embodiments, the ALD layer 220 may already be formed as part of frontend production, e.g. the ALD layer 220 may be deposited already in the frontend fab on top of the first dielectric layer(s) 128, e.g. an imide or an other organic passivation layer. Provided that the second dielectric layer 220 is thin enough (e.g., up to approximately 100 nm), a structuring may not be necessary, because the probe card needles used during the wafer test and the bond are able to break through the ALD layer 220.

Providing the ALD layer 220 on a solderable frontside, e.g., a chip pad 108 to be used for a solder contact, may in some cases not be feasible, due to an inhibiting effect of the ALD layer 220 for intermetallic reactions (which may be necessary for forming solder joints). In other cases, a soldering on the front side may be possible, for example by providing a flux that is able to resolve the ALD layer.

In various embodiment, the ALD layer 220 may be embedded into two organic passivation layers (e.g., imide). For example, the (e.g., top) first dielectric layer 128 may be an organic passivation layer, and a third dielectric layer (not shown in the figures), e.g. an organic, e.g. imide layer may be arranged over the ALD layer 220.

In this case, the ALD layer 220 may be fully or partly removed from the contact pad 108 using the third dielectric layer (e.g., the top imide layer) as an etch mask. Thereby, standard wire bonding or soldering may be enabled.

No passivation required on the wafer, which may enable safe metallisation surfaces for reliable wirebonding.

The chip arrangement 200 may allow for faster development projects (reduced risk of reliability fails, fewer learning cycles), more flexibility in the use of encapsulants, in particular mold compounds (less or no interaction between mold and termination, faster introduction of new mold compounds and housings, for shrinking of a width of the chip termination portion and thereby a chip cost reduction, and/or a process cost reduction (e.g. reduction or elimination of process steps for classical chip passivation layer stacks).

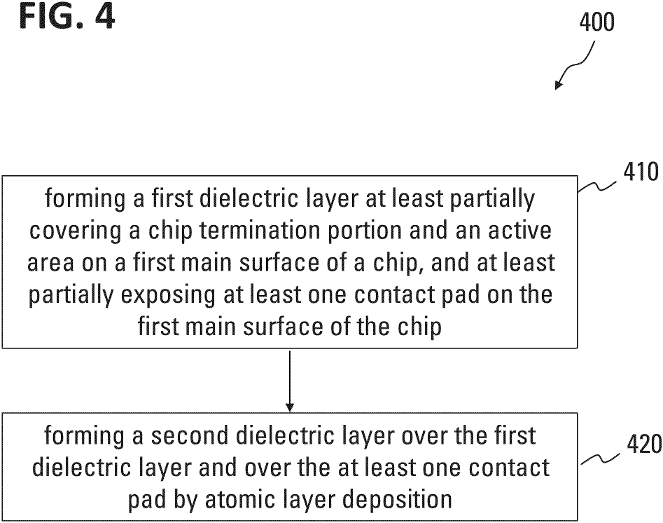

FIG. 4 shows a flow diagram 400 of a method of forming a chip arrangement in accordance with various embodiments.

The method may include forming a first dielectric layer at least partially covering a chip termination portion and an active area on a first main surface of a chip, and at least partially exposing at least one contact pad on the first main surface of the chip (in 410), and forming a second dielectric layer over the first dielectric layer and over the at least one contact pad by atomic layer deposition (in 420).

Various examples will be illustrated in the following:

Example 1 is a chip arrangement. The chip arrangement may include a chip including a first main surface, wherein the first main surface includes an active area, a chip termination portion, and at least one contact pad, a first dielectric layer at least partially covering the chip termination portion and the active area, and at least partially exposing the at least one contact pad, and a second dielectric layer formed by atomic layer deposition over the first dielectric layer and over the at least one contact pad.

In Example 2, the subject-matter of Example 1 may optionally include that the first dieletric layer has a larger thickness than the second dielectric layer.

In Example 3, the subject-matter of Example 1 or 2 may optionally include that a material of the first dielectric layer is different from a material of the second dielectric layer.

In Example 4, the subject-matter of any of Examples 1 to 3 may optionally include that the first dielectric layer includes or consists of at least one of a group of materials, the group including an organic material, an oxide, and a nitride.

In Example 5, the subject-matter of any of Examples 1 to 4 may optionally include that the second dielectric layer includes or consists of at least one of a group of materials, the group including Al₂O₃, SiO₂, HfO₂, ZrO₂, TiO₂, Ta₂O₅, AlN,BN, TiN, TaN, Si₃N₄, and an organic material.

In Example 6, the subject-matter of Example 5 may optionally include that the first dielectric layer includes or consists of an imide.

In Example 7, the subject-matter of any of Examples 1 to 6 may optionally include that the chip includes a second main surface opposite the first main surface, and side surfaces connecting the first main surface and the second main surface, and that the second dielectric layer further at least partially covers the side surfaces.

In Example 8, the subject-matter of any of Examples 1 to 7 may optionally further include that a thickness of the second dielectric layer is in a range from about 2 nm to about 100 nm.

In Example 9, the subject-matter of any of Examples 1 to 8 may optionally further include a third dielectric layer at least partially covering the second dielectric layer.

In Example 10, the subject-matter of Example 9 may optionally include that the third dielectric layer includes or consists of at least one of a group of materials, the group including Al₂O₃, SiO₂, HfO₂, ZrO₂, TiO₂, Ta₂O₅, AlN, BN, TiN, TaN, Si₃N₄, and an organic material.

In Example 11, the subject-matter of any of Examples 1 to 10 may optionally further include a metal contact structure, the metal contact structure electrically contacting the contact pad.

In Example 12, the subject-matter of Example 11 may optionally include that the second dielectric layer further at least partially covers the metal contact structure.

In Example 13, the subject-matter of any of Examples 1 to 12 may optionally further include a carrier, wherein the chip is mounted on the carrier, wherein the carrier includes exposed metal, and wherein the second dielectric layer further at least partially covers the exposed metal of the carrier.

In Example 14, the subject-matter of Example 13 may optionally include that the exposed metal is arranged on a side of the carrier to which the chip is mounted.

Example 15 is a chip package. The chip package may include the chip arrangement of any of Examples 1 to 14, and packaging material at least partially encapsulating the chip.

In Example 16, the subject-matter of Example 15 may optionally include that the packaging material is in direct contact with the second dielectric layer.

In Example 17, the subject-matter of Example 15 may optionally include that the chip arrangement includes the third dielectric layer of Example 9, and that the packaging material is in direct contact with the third dielectric layer.

In Example 18, the subject-matter of any of Examples 15 to 16 may optionally include that the chip arrangement includes the carrier of Example 14, and that the packaging material at least partially encapsulates the carrier.

Example 19 is a method of forming a chip arrangement. The method may include forming a first dielectric layer at least partially covering a chip termination portion and an active area on a first main surface of a chip, and at least partially exposing at least one contact pad on the first main surface of the chip, and forming a second dielectric layer over the first dielectric layer and over the at least one contact pad by atomic layer deposition.

In Example 20, the subject-matter of Example 19 may optionally include that the first dielectric layer has a larger thickness than the second dielectric layer.

In Example 21, the subject-matter of Example 19 or 20 may optionally include that a material of the first dielectric layer is different from a material of the second dielectric layer.

In Example 22, the subject-matter of any of Examples 19 to 21 may optionally include that the first dielectric layer includes or consists of at least one of a group of materials, the group including an organic material, an oxide, and a nitride.

In Example 23, the subject-matter of any of Examples 19 to 22 may optionally include that the second dielectric layer includes or consists of at least one of a group of materials, the group including Al₂O₃, SiO₂, HfO₂, ZrO₂, TiO₂, Ta₂O₅, AlN, BN, TiN, TaN, Si₃N₄, and an organic material.

In Example 24, the subject-matter of Example 23 may optionally include that the first dielectric layer includes or consists of an imide.

In Example 25, the subject-matter of any of Examples 19 to 24 may optionally include that the chip includes a second main surface opposite the first main surface, and side surfaces connecting the first main surface and the second main surface, and that the second dielectric layer further at least partially covers the side surfaces.

In Example 26, the subject-matter of any of Examples 19 to 25 may optionally include that a thickness of the second dielectric layer is in a range from about 2 nm to about 100 nm.

In Example 27, the subject-matter of any of Examples 19 to 26 may optionally include forming a third dielectric layer at least partially covering the second dielectric layer.

In Example 28, the subject-matter of Example 27 may optionally include that the third dielectric layer includes or consists of at least one of a group of materials, the group including Al₂O₃, SiO₂, HfO₂, ZrO₂, TiO₂, Ta₂O₅, AlN, BN, TiN, TaN, Si₃N₄, and an organic material.

In Example 29, the subject-matter of Example 28 may optionally include forming a layer stack including the second dielectric layer and the third dielectric layer and at least one further dielectric layer, for example with alternating layer materials.

In Example 30, the subject-matter of any of Examples 19 to 29 may optionally include that the second dielectric layer is formed at a wafer level or during backend processing.

In Example 31, the subject-matter of any of Examples 19 to 30 may optionally further include electrically contacting the contact pad with a metal contact structure.

In Example 32, the subject-matter of Examples 29 and 31 may optionally include that the electrically contacting includes penetrating the second dielectric layer during the contacting process.

In Example 33, the subject-matter of any of Examples 19 to 32 may optionally include that the electrically contacting is executed before the forming of the second dielectric layer.

In Example 34, the subject-matter of any of Examples 19 to 33 may optionally include that the second dielectric layer further at least partially covers the metal contact structure.

In Example 35, the subject-matter of any of Examples 19 to 34 may optionally include that mounting the chip onto a carrier includes that the carrier includes exposed metal, and thtat the second dielectric layer further at least partially covers the exposed metal of the carrier.

In Example 36, the subject-matter of Example 35 may optionally include that the exposed metal is arranged on a side of the carrier to which the chip is mounted.

Example 37 is a method of forming a chip package. The method may include forming a chip arrangement in accordance with the method of any of Examples 19 to 36, and least partially encapsulating the chip with a packaging material.

In Example 38, the subject-matter of Example 37 may optionally include that the packaging material is in direct contact with the second dielectric layer.

In Example 39, the subject-matter of Example 38 may optionally include that the method includes the forming the third dielectric layer in accordance with Example 27, and that the packaging material is in direct contact with the third dielectric layer.

In Example 34, the subject-matter of any of Examples 19 to 33 may optionally include that the method includes the mounting of the chip onto the carrier in accordance with Example 35, and further includes at least partially encapsulating the carrier with the packaging material.

While the invention has been particularly shown and described with reference to specific embodiments, it should be understood by those skilled in the art that various changes in form and detail may be made therein without departing from the spirit and scope of the invention as defined by the appended claims. The scope of the invention is thus indicated by the appended claims and all changes which come within the meaning and range of equivalency of the claims are therefore intended to be embraced.

What is claimed is:

1. A chip arrangement, comprising:
a chip comprising a first main surface, wherein the first main surface comprises an active area, a chip termination portion, and at least one contact pad;
a first dielectric layer at least partially covering the chip termination portion and the active area, and at least partially exposing the at least one contact pad; and
a second dielectric layer formed by atomic layer deposition over the first dielectric layer and over the at least one contact pad.

2. The chip arrangement of claim 1,
wherein the first dielectric layer has a larger thickness than the second dielectric layer.

3. The chip arrangement of claim 1,
wherein a material of the first dielectric layer is different from a material of the second dielectric layer.

4. The chip arrangement of claim 1,
wherein the first dielectric layer includes or consists of at least one of a group of materials, the group comprising:
an organic material;
an oxide; and
a nitride.

5. The chip arrangement of claim 1,
wherein the second dielectric layer includes or consists of at least one of a group of materials, the group comprising:
Al₂O₃;
SiO₂;
HfO₂;
ZrO₂;
TiO₂;
Ta₂O₅;
AlN;
BN;
TiN;
TaN; and
Si₃N₄.

6. The chip arrangement of claim 5,
wherein the first dielectric layer includes or consists of an imide.

7. The chip arrangement of claim 1,
wherein the chip comprises a second main surface opposite the first main surface, and side surfaces connecting the first main surface and the second main surface, and
wherein the second dielectric layer further at least partially covers the side surfaces.

8. The chip arrangement of claim 1, further comprising:
wherein a thickness of the second dielectric layer is in a range from about 2 nm to about 100 nm.

9. The chip arrangement of claim 1, further comprising:
a third dielectric layer at least partially covering the second dielectric layer.

10. The chip arrangement of claim 9,
wherein the third dielectric layer includes or consists of at least one of a group of materials, the group comprising:
Al₂O₃;
SiO₂;
HfO₂;
ZrO₂;
TiO₂;
Ta₂O₅;
AlN;
BN;
TiN;
TaN;
Si₃N₄; and
an organic material.

11. The chip arrangement of claim 1, further comprising:
a metal contact structure, the metal contact structure electrically contacting the contact pad.

12. The chip arrangement of claim 11,
wherein the second dielectric layer further at least partially covers the metal contact structure.

13. The chip arrangement of claim 1, further comprising:
a carrier;
wherein the chip is mounted on the carrier,
wherein the carrier comprises exposed metal; and
wherein the second dielectric layer further at least partially covers the exposed metal of the carrier.

14. The chip arrangement of claim 13,
wherein the exposed metal is arranged on a side of the carrier to which the chip is mounted.

15. A chip package, comprising:
the chip arrangement of claim 1; and
packaging material at least partially encapsulating the chip.

16. The chip package of claim 15,
wherein the packaging material is in direct contact with the second dielectric layer.

17. The chip package of claim 15,
wherein the chip arrangement comprises the third dielectric layer of claim 9, and
wherein the packaging material is in direct contact with the third dielectric layer.

18. The chip package of claim 15,
wherein the chip arrangement comprises the carrier of claim 14, and
wherein the packaging material at least partially encapsulates the carrier.

19. A method of forming a chip arrangement, the method comprising:
forming a first dielectric layer at least partially covering a chip termination portion and an active area on a first main surface of a chip, and at least partially exposing at least one contact pad on the first main surface of the chip; and
forming a second dielectric layer over the first dielectric layer and over the at least one contact pad by atomic layer deposition.

20. The method of claim 19,
wherein the first dielectric layer has a larger thickness than the second dielectric layer,
wherein a material of the first dielectric layer is different from a material of the second dielectric layer,
wherein the chip comprises a second main surface opposite the first main surface, and side surfaces connecting the first main surface and the second main surface,
wherein the second dielectric layer further at least partially covers the side surfaces, and
forming a third dielectric layer at least partially covering the second dielectric layer.
